(19) United States
(12) Patent Application Publication
(10) Pub. No.: US 2008/0252359 A1
(43) Pub. Date: Oct. 16, 2008

(54) SWITCH CONTROL CIRCUIT FOR EXTERNAL HARD DISK

(75) Inventors: Jian-Ming Sung, Taipei Hsien (TW); Yi-Wen Chou, Taipei Hsien (TW)

Correspondence Address: WPAT, PC;INTELLECTUAL PROPERTY ATTORNEYS, 2030 MAIN STREET, SUITE 1300, IRVINE, CA, 92614, US

(73) Assignee: CHENG UEI PRECISION INDUSTRY CO., LTD, Taipei Hsien (TW)

(21) Appl. No.: 11/735,312

(22) Filed: Apr. 13, 2007

(51) Int. Cl. H03K 17/687

(52) U.S. Cl. 327/434

(57) ABSTRACT

A switch control circuit includes a N-channel MOSFET, a first bleeder unit, a P-channel MOSFET and a second bleeder unit. The N-channel MOSFET has a first input terminal, a first output terminal and a first control terminal. The first output terminal is connected to ground. The first bleeder unit has a voltage-dividing function to the voltage from an input and output interface of a computer. The first bleeder unit is connected with the first control terminal and the first output terminal of the N-channel MOSFET. The P-channel MOSFET has a second input terminal, a second output terminal and a second control terminal. The second output terminal is connected to the working voltage terminal of the external hard disk. The second bleeder unit is connected between the external power supply and the first input terminal of the N-channel MOSFET. The P-channel MOSFET is connected with the first bleeder unit.

### BACKGROUND OF THE INVENTION

1. Field of the Invention

The present invention relates to a switch control circuit, and more particularly to a switch control circuit for external hard disk.

2. The Related Art

Following the development of the science and technology, people need to deal with more and more digital data in daily work. For the larger memory space and smaller volume, the external hard disks are generally used to store digital data in the computer and be carried with people. When the digital data in the external hard disk is needed, people could transfer the digital data to the computer.

Commonly the external hard disk and the computer are established a connection by an USB transmission cable transferring digital data therebetween. The external hard disk and an external power supply are established a connection by a power cord in order to supply current and voltage to the external hard disk from the external power supply. A conventional external hard disk disclosed in U.S. public No. 2006/0274505 issued Dec. 7, 2006 includes a retaining base for mounting a hard disk. The retaining base has adjusting robs that can be moved vertically up and down. The remaining base and the hard disk are covered by a heat dissipating cover.

However, the external power supply supplies power to the external hard disk continuously when the external hard disk is connected with the external power supply. The continuous power supply leads to a waste of energy resource. Therefore, a new-designed plan for the external hard disk to overcome the deficiency is required.

### SUMMARY OF THE INVENTION

Accordingly, an object of the present invention is to provide a switch control circuit for an external hard disk. The switch control circuit of the external hard disk includes a N-channel MOSFET, a first bleeder unit, a P-channel MOSFET and a second bleeder unit. The N-channel MOSFET has a first input terminal, a first output terminal and a first control terminal. The first output terminal is connected to ground. The first bleeder unit has a voltage-dividing function to the voltage provided from an input and output interface of a computer. The first bleeder unit is connected with the first control terminal and the first output terminal of the N-channel MOSFET for controlling the connection and disconnection of the N-channel MOSFET. The P-channel MOSFET has a second input terminal, a second output terminal and a second control terminal. The second output terminal is connected to the working voltage terminal of the external hard disk. The second bleeder unit is connected between the external power supply and the first input terminal of the N-channel MOSFET. The second input terminal and the second control terminal of the P-channel MOSFET are connected with a higher potential and the lower potential of the first bleeder unit respectively. The first bleeder unit divides the voltage from the input and output interface to make the N-channel MOSFET be connected, then the second bleeder unit makes the P-channel MOSFET be connected.

As described above, the N-channel MOSFET is controlled by the first bleeder unit that has a voltage-dividing function to the voltage provided from the input and output interface. The N-channel MOSFET makes the second bleeder circuit to control the P-channel MOSFET. Thereby the connection and the disconnection of the external power supply and the working voltage terminal of the external hard disk are controlled by the P-channel MOSFET. Therefore the external power supply provides current and voltage for the external hard disk only while the external hard disk 100 and the computer 200 being established a connection.

### BRIEF DESCRIPTION OF THE DRAWINGS

The present invention will be apparent to those skilled in the art by reading the following description of a preferred embodiment thereof, with reference to the attached drawings, in which:

FIG. 1 is a schematic view of an external hard disk connected with a computer and an external power supply; and

FIG. 2 is a circuitry of a switch control circuit for the external hard disk.

### DETAILED DESCRIPTION OF THE PREFERRED EMBODIMENT

For facilitating understanding, like components are designated by like reference numerals throughout the embodiment of the invention as shown in the attached drawings.

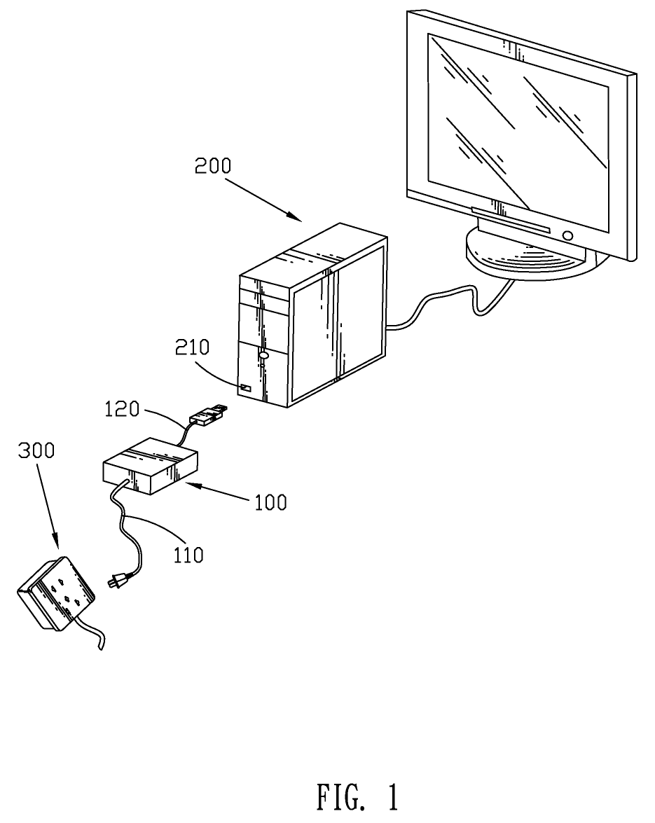

Now referring to FIG. 1, an external hard disk 100 and an input and output interface 210 of a computer 200 are established a connection by an USB transmission cable 120 transmitting digital data between the computer 200 and the external hard disk 100. The external hard disk 100 and an external power supply 300 are established a connection by a power cord 110 in order to supply current and voltage to the external hard disk 100 from the external power supply 300.

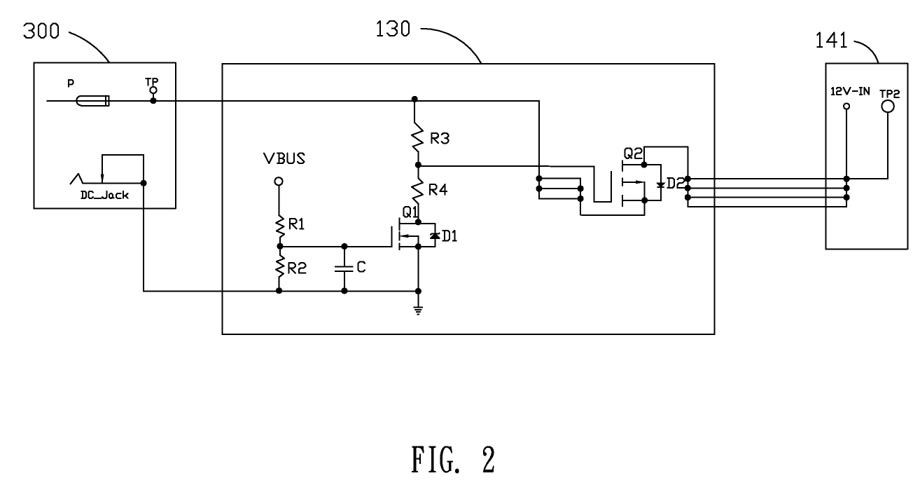

With reference to FIG. 2, the external hard disk 100 has a switch control circuit 130. The connection and the disconnection between the external power supply 300 and the external hard disk 100 are controlled by the switch control circuit 130 in the external hard disk 100. The switch power supply 130 includes a first switch unit Q1, a first resistance R1, a second resistance R2, a second switch unit Q2, a third resistance R3 and a fourth resistance R4.

The first terminal of the first resistance R1 is a voltage terminal, the input and output interface 210 of the computer 200 brings a 5V voltage to the voltage terminal when the external hard disk 100 is connected to the computer 200 by an USB transmission cable. The second terminal of the first resistance R1 is connected with the first terminal of the second resistance R2. The second terminal of the second resistance R2 is connected to ground. Therefore a first bleeder unit is formed by the series-connection of the first resistance R1 and the second resistance R2. The first bleeder unit has a voltage-dividing function to the voltage from the input and output interface 210 of the computer 200.

The first switch unit Q1 is a N-channel MOSFET, which includes a first input terminal, a first output terminal and a first control terminal. The first control terminal is connected between the first resistance R1 and the second resistance R2. The connection and disconnection of the first input terminal and the first output terminal of the first switch unit Q1 are controlled by the first bleeder unit. A reverse diode D1 is posited between the first input terminal and the first output terminal of the first switch unit Q1. The first output terminal is connected to ground. A regulated capacitance C is connected between the first control terminal and the first output terminal in order to avoid the damage of the first switch unit Q1 in a blink of high pressure.

The first terminal of the fourth resistance R4 is connected with the first input terminal of the first switch unit Q1. Moreover the second terminal of the fourth resistance R4 is connected with the first terminal of the third resistance R3. The second terminal of the third resistance R3 is connected to the external power supply 300. A second bleeder unit is formed by the series-connection of the third resistance R3 and the fourth resistance R4. The second switch unit Q2 has a voltage-dividing function to the working voltage from the external power supply 300.

The second switch unit Q2 is a P-channel MOSFET, which includes a second input terminal, a second output terminal and a second control terminal. The second control terminal is connected between the third resistance R3 and the fourth resistance R4. The connection and disconnection of the second input terminal and the second output terminal of the second switch unit Q2 are controlled by the second bleeder circuit. A reverse diode D2 is posited between the second input terminal and the second output terminal of the second switch unit Q2. The second input terminal is connected to the external power supply 300. The external power supply 300 brings 12V voltage to the second input terminal. The second output terminal is connected with a working voltage terminal 141 of the external hard disk 100.

Now taking description to the working principle of the switch control circuit 130. When the external hard disk 100 and the input and output interface 210 of the computer 200 are established a connection by the USB transmission cable 120, the input and output interface 210 brings a 5V voltage. The voltage drop of the first control terminal and the first output terminal of the first switch unit Q1 is nearly 2.5V after the voltage-dividing being done by the first resistance R1 and the second resistance R2. Therefore the first input terminal and the first output terminal of the first switch unit Q1 are connected. At this time, the first terminal of the fourth resistance R4 is equal to being connected to ground. Thus the external power supply 300, the third resistance R3 and the fourth resistance R4 form a circuit. The voltage drop of the second control terminal and the second input terminal of the second switch unit Q2 is nearly 1.1V after the voltage-dividing being done to the 12V voltage provided from the external power supply 300 by the third resistance R3 and the fourth resistance R4. At present, the second input terminal and the second output terminal of the second switch unit Q2 are connected. Therefore the second output terminal of the second switch unit Q2 has a 12V voltage. Thereby the external power supply 300 supplies a 12V working voltage to the working voltage terminal 141 of the external hard disk 100.

When the connection of the external hard disk 100 and the computer 200 are disconnected, the first terminal of the first resistance R1 has no voltage. The first input terminal and the first output terminal of the first switch unit Q1 are disconnected because the voltage drop of the first output terminal and the first control terminal of the first switch unit Q1 are 0V, so the external power supply 300, the third resistance R3 and the fourth resistance R4 can not form a circuit. At this moment, there is no voltage drop between the second output terminal and the second control terminal of the second switch unit Q2, therefore the second output terminal and the second input terminal of the second switch unit Q2 are disconnected. Thus the external power supply 300 is disconnected with the working voltage terminal 141 of the external hard disk 100.

As described above, the first switch unit Q1 is controlled by the first bleeder unit that has a voltage-dividing function to the voltage provided from the input and output interface 210. The first switch unit Q1 makes the second bleeder circuit to control the second switch unit Q2. Thereby the connection and the disconnection of the external power supply and the working voltage terminal of the external hard disk are controlled by the second switch unit Q2. Therefore the external power supply 300 provides current and voltage for the external hard disk 100 only while the external hard disk 100 and the computer 200 being established a connection.

The foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

What is claimed is:

1. A switch control circuit of the external hard disk, comprising:
a N-channel MOSFET, having a first input terminal, a first output terminal and a first control terminal, the first output terminal connected to ground;
a first bleeder unit having a voltage-dividing function to the voltage provided from an input and output interface of a computer, the first bleeder unit connected with the first control terminal and the first output terminal of the N-channel MOSFET for controlling the connection and disconnection of the N-channel MOSFET;
a P-channel MOSFET, having a second input terminal, a second output terminal and a second control terminal, the second output terminal connected with the working voltage terminal of the external hard disk; and
a second bleeder unit connected between the external power supply and the first input terminal of the N-channel MOSFET, the second input terminal and the second control terminal of the P-channel MOSFET connected to a higher potential and the lower potential of the first bleeder unit respectively;
wherein the first bleeder unit divides the voltage from the input and output interface to make the N-channel MOSFET be connected, then the second bleeder unit makes the P-channel MOSFET be connected.

2. The switch control circuit as claimed in claim 1, wherein the first bleeder unit has a first resistance and a second resistance series-connected, the first resistance connected to the input and output interface of the computer and the second resistance connected to ground, the first control terminal of the N-channel MOSFET is connected between the first resistance and the second resistance, the first output terminal of the N-channel MOSFET is connected to ground, the second bleeder unit has a third resistance and a fourth resistance series-connected, the third resistance connected to the external power supply, the fourth resistance connected with the first input terminal of the N-channel MOSFET, the second control terminal of the P-channel MOSFET is connected between the third resistance and the fourth resistance, the second input terminal of the P-channel MOSFET is connected to the external power supply, the second output terminal of the P-channel MOSFET is connected to the working voltage terminal of the external hard disk.

3. The switch control circuit as claimed in claim 1, wherein a regulated capacitance is connected between the first input terminal and the first output terminal of the N-channel MOSFET in order to avoid the damage of the N-channel MOSFET in a blink of high pressure.

4. The switch control circuit as claimed in claim 1, wherein a reverse diode is posited between the first input terminal and the first output terminal of the N-channel MOSFET.

5. The switch control circuit as claimed in claim 1, wherein a reverse diode is posited between the second input terminal and the second output terminal of the P-channel MOSFET.

6. A switch control circuit of the external hard disk, comprising:
a first switch unit, having a first input terminal, a first output terminal and a first control terminal, the first input terminal and the first output terminal connected while the voltage drop between the first control terminal and the first output terminal being higher than a certain value, the first output terminal connected to ground;
a first bleeder unit having a voltage-dividing function to the voltage provided from an input and output interface of a computer, the first bleeder unit connected with the first control terminal and the first output terminal of the first switch unit for controlling the connection and disconnection of the first switch unit;
a second switch unit, having a second input terminal, a second output terminal and a second control terminal, the second input terminal and the second output terminal connected while the voltage drop between the second input terminal and the second control terminal being higher than a certain value, the second output terminal connected with the working voltage terminal of the external hard disk; and
a second bleeder unit connected between the external power supply and the first input terminal of the first switch unit, the second input terminal and the second control terminal of the second switch unit connected to a higher potential and the lower potential of the first bleeder unit respectively;
wherein the first bleeder unit divides the voltage from the input and output interface to make the first switch unit be connected, then the second bleeder unit makes the second switch unit be connected.
